(19) United States
(12) Patent Application Publication
(10) Pub. No.: US 2020/0066216 A1
(43) Pub. Date: Feb. 27, 2020

(54) DRIVE METHOD FOR DISPLAY DEVICE, DRIVE SYSTEM FOR DISPLAY DEVICE, AND DISPLAY DEVICE

(71) Applicants: HKC CORPORATION LIMITED, Shenzhen (CN); CHONGQING HKC OPTOELECTRONICS TECHNOLOGY CO., LTD., Chongqing (CN)

(72) Inventors: Shuixiu HU, Chongqing (CN); Dongsheng GUO, Chongqing (CN)

(21) Appl. No.: 16/311,878

(22) PCT Filed: Nov. 26, 2018
(86) PCT No.: PCT/CN2018/117469

§ 371 Date: Dec. 20, 2018

(30) Foreign Application Priority Data
Feb. 25, 2018 (CN) 201810159001.9

(51) Int. Cl. G09G 3/36; G02F 1/1362; H01L 27/12

(52) U.S. Cl. CPC G09G 3/36; H01L 27/124; G02F 1/136286

(57) ABSTRACT

A drive method for a display device, a drive system for a display device, and a display device are disclosed. The drive method enables a polarity of a common electrode voltage of a display panel to be switched between different frames, to avoid a color deviation occurring in an image of the display panel.

### BACKGROUND

### Technical Field

This application relates to the field of display technologies, and in particular, to a drive method for a display device, a drive system for a display device, and a display device.

### Related Art

Thin film transistor-liquid crystal displays (TFT-LCD) are generally data-driven in a drive manner of using a common electrode direct current voltage or in a drive manner of modulating a common electrode voltage. However, when the TFT-LCDs are data-driven in the drive manner of modulating a common electrode voltage, a common electrode of a display panel has a relatively large parasitic capacitance. Therefore, a modulation speed of a common electrode voltage becomes low, and it takes time to modulate the common electrode voltage, resulting in display color deviation occurring in the display panel in the time, and severely reducing image quality.

### SUMMARY

An objective of this application is to provide a drive method for a display device, a drive system for a display device, and a display device, to resolve technical problems in the exemplary technology, including but not limited to, that a modulation speed of a common electrode voltage is relatively low, and it takes time to modulate the common electrode voltage, resulting in display color deviation occurring in a display panel in a modulation time, and severely reducing image quality.

To resolve the foregoing technical problems, a technical solution used in an embodiment of this application is: a drive method for a display device, where the display device comprises a display panel, a driver, and a controller, the driver is electrically connected to the display panel, the controller is electrically connected to the driver, the controller controls the driver to perform the following drive method, and the drive method includes:

modulating a common electrode voltage for an n-th frame into a target common electrode voltage within a frame interval time period; and

modulating the target common electrode voltage into a common electrode voltage for an (n+1)-th frame when the frame interval time period ends, where the target common electrode voltage is greater than the common electrode voltage for the (n+1)-th frame which is greater than the common electrode voltage for the n-th frame, wherein n≥1 and n is selected from an odd number and an even number.

Another objective of this application is to provide a drive system for a display device, where the display device comprises a display panel, a driver, and a controller, the driver is electrically connected to the display panel, the controller is electrically connected to the driver, the controller controls the driver to execute program modules in the following drive system, and the drive system includes:

a first common electrode voltage modulator configured to modulate a common electrode voltage for an n-th frame into a target common electrode voltage within a frame interval time period; and

a second common electrode voltage modulator configured to modulate the target common electrode voltage into a common electrode voltage for an (n+1)-th frame when the frame interval time period ends,

wherein the target common electrode voltage is greater than the common electrode voltage for the (n+1)-th frame which is greater than the common electrode voltage for the n-th frame, wherein n≥1 and n is selected from an odd number and an even number.

Still another objective of this application is to provide display device, including a display panel, a driver, and a controller, wherein the driver is electrically connected to the display panel, the controller is electrically connected to the driver, the driver comprises a storage medium with a computer program stored therein, when the program is executed by a processor, the following drive method for the display device is implemented, and the drive method includes:

modulating a common electrode voltage for an n-th frame into a target common electrode voltage within a frame interval time period; and

modulating the target common electrode voltage into a common electrode voltage for an (n+1)-th frame when the frame interval time period ends, wherein

the target common electrode voltage is greater than the common electrode voltage for the (n+1)-th frame which is greater than the common electrode voltage for the n-th frame, wherein n≥1 and n is selected from an odd number and an even number.

In the drive method for a display device provided in some embodiments of this application, a common electrode voltage for a frame is modulated into a target common electrode voltage within a frame interval time period, and the target common electrode voltage is then modulated into a common electrode voltage for a next frame after the frame interval time period, so that a modulation time period of a common electrode voltage of a display panel is shortened, accurate switching between the two frames is improved, and a color deviation phenomenon of the display panel is eliminated. Problems in the exemplary technology that a modulation speed of the common electrode voltage is low and image quality of the display panel is relatively poor are resolved.

### BRIEF DESCRIPTION OF THE DRAWINGS

To make the technical solutions of the present invention clearer, the accompanying drawings for illustrating the embodiments of the present invention or the prior art are given briefly below. Apparently, the accompanying drawings are only for the exemplary purpose, and persons of ordinary skill in the art can derive other drawings from the accompanying drawings without creative efforts.

FIG. 1 is a schematic diagram of a voltage corresponding to a drive manner of modulating a common electrode voltage in an example according to an embodiment of this application;

FIG. 2 is a schematic diagram of modulation of a common electrode voltage in an example according to an embodiment of this application;

FIG. 3 is a schematic flowchart of a drive method according to an embodiment of this application;

FIG. 4 is a diagram of a module structure of a display device according to an embodiment of this application;

FIG. 5 is a schematic diagram of another modulation of a common electrode voltage according to an embodiment of this application;

FIG. 6 is a schematic diagram of another modulation of a common electrode voltage according to an embodiment of this application;

FIG. 7 is a schematic diagram of another modulation of a common electrode voltage according to an embodiment of this application;

FIG. 8 is a schematic flowchart of another drive method according to an embodiment of this application;

FIG. 9 is a diagram of a module structure of a drive system according to an embodiment of this application;

FIG. 10 is a diagram of a module structure of another drive system according to an embodiment of this application;

FIG. 11 is a diagram of a module structure of a first common electrode voltage modulator according to an embodiment of this application; and

FIG. 12 is a diagram of a module structure of a display device according to an embodiment of this application.

### DETAILED DESCRIPTION

To make objectives, technical solutions and advantages of the present invention more understandable and comprehensible, the present invention is further described in detail below with reference to accompanying drawings and embodiments. It should be understood that the embodiments herein are provided for describing the present invention and not intended to limit the present invention.

It should be noted that when an element is referred to as being “fixed” to or “disposed” on another element, it can be directly fixed to or disposed on the other element or intervening elements may also be present. When an element is referred to as being “coupled” or “connected” to another element, it can be directly or indirectly coupled or connected to the other element. Orientation or position relationships indicated by the terms such as “on”, “below”, “left”, and “right” are based on orientation or position relationships shown in the accompanying drawings, and are used only for ease of illustration description, rather than indicating or implying that the mentioned apparatus or component must have a particular orientation or must be constructed and operated in a particular orientation. Therefore, such terms should not be construed as limiting of this application. Persons of ordinary skill in the art can understand the specific meaning of these terms according to specific situations. The terms such as “first” and “second” are used only for the purpose of description, and should not be understood as indicating or implying the relative importance or implicitly specifying the number of the indicated technical features. Unless otherwise particularly defined, “a plurality of” means two or more than two.

The technical solutions of this application are described in detail below with reference to the accompanying drawings and embodiments.

In the TFT-LCD field, a pixel voltage of a display panel is determined based on a voltage difference between a data voltage and a common electrode voltage. The voltage different is directly related to a transmittivity characteristic of liquid crystal in pixels. A larger voltage difference indicates a larger deflection angle of liquid crystal molecules in the liquid crystal and larger transmittivity of the liquid crystal.

In an application, the data voltage is a voltage that is output by a data driver chip, and the data driver chip may be a source driver IC. Different voltage differences correspond to different gray-scales. Output precision of the data voltage that is output by the data driver chip needs to be improved to improve the number of gray-scales, so that the data driver chip outputs data voltages having different values.

In an application, polarity reversal can be achieved by changing a polarity of a drive voltage applied to the pixels. The drive voltage applied to the pixels can be negative by making the voltage difference between the data voltage and the common electrode voltage negative, and the drive voltage applied to the pixels can be positive by making the voltage difference between the data voltage and the common electrode voltage positive. There are two common manners of performing data driving on the display panel: first, a drive manner of using a common electrode direct current voltage; and second, a drive manner of modulating a common electrode voltage.

The drive manner of using a common electrode direct current voltage is maintaining the common electrode voltage unchanged. To achieve polarity reversal, the common electrode voltage is generally set to a data average value of the largest data voltage and the smallest data voltage. For example, if the largest data voltage is 10 V, and the smallest data voltage is 0 V, the common electrode voltage is 5 V.

The drive manner of modulating a common electrode voltage is enabling the common electrode voltage to vary as the polarity of the drive voltage changes, so that a common electrode voltage between two neighboring frames is modulated. Generally, when the polarity of the drive voltage is positive, the common electrode voltage is modulated to be greater than the largest data voltage. When the polarity of the drive voltage is negative, the common electrode voltage is modulated to be less than the smallest data voltage.

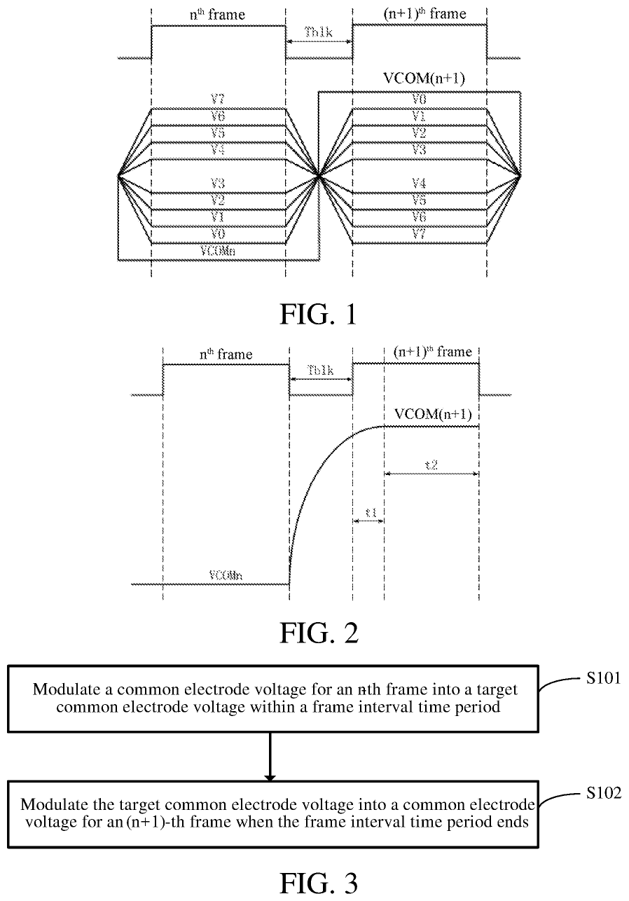

FIG. 1 is a schematic diagram of a voltage corresponding to a drive manner of modulating a common electrode voltage.

FIG. 1 exemplarily shows data voltages and a common electrode voltage that correspond to the n-th frame including eight gray-scales. The data voltages corresponding to the eight gray-scales are respectively represented by V0, V1, . . . , and V7 (arranged in ascending order of the data voltages), and the common electrode voltage is represented by VCOMn. The common electrode voltage VCOMn is less than the smallest data voltage V0 corresponding to the n-th frame, and a drive polarity for the n-th frame is negative.

FIG. 1 further exemplarily shows data voltages and a common electrode voltage that correspond to the (n+1)-th frame including eight gray-scales. The data voltages corresponding to the eight gray-scales are respectively represented by V7, V6, . . . , and V0 (arranged in ascending order of the voltages), and the common electrode voltage is represented by VCOM(n+1). The common electrode voltage VCOM(n+1) is greater than the largest data voltage V0 corresponding to the (n+1)-th frame, and a drive polarity for the (n+1)-th frame is positive.

In FIG. 1, the common electrode voltage VCOMn is modulated into the common electrode voltage VCOM(n+1) within a frame interval time period Tblk between the n-th frame and the (n+1)-th frame.

n≥1 and n is an odd number or an even number, and the frame interval time period Tblk is a time interval in which the n-th frame is switched to the (n+1)-th frame.

In FIG. 1, the common electrode voltage VCOMn corresponding to the n-th frame is smaller than the smallest data voltage V0, and the common electrode voltage VCOM(n+1) corresponding to the (n+1)-th frame is greater than the largest data voltage V0.

In an application, a parasitic capacitance of a common electrode of a display panel, particularly a large-size display panel, is relatively large, and a voltage of the parasitic capacitance cannot suddenly change. Therefore, the common electrode voltage for the n-th frame cannot be switched to the common electrode voltage for the (n+1)-th frame within the frame interval time period. That is, the parasitic capacitance causes a modulation speed of the common electrode voltage to be low, and consequently, when a data driver chip starts to output a data voltage to perform data driving on pixels for the (n+1)-th frame, the common electrode voltage is not completely modulated, causing inconsistency between a voltage difference between the data voltage and the common electrode voltage and a normal data drive voltage required by the pixels and abnormality of a pixel gray-scale. Therefore, color deviation occurs in the display panel, and image quality is severely affected.

FIG. 2 is a schematic diagram of modulation of a common electrode voltage based on a drive manner of modulating a common electrode voltage.

In FIG. 2, a common electrode voltage VCOMn corresponding to the n-th frame is modulated to a common electrode voltage VCOM(n+1) corresponding to the (n+1)-th frame within a frame interval time period Tblk plus a delay time t1.

The frame interval time period Tblk is an ideal modulation time of the common electrode voltage.

However, due to impact of a parasitic capacitance, actually, the common electrode voltage is completely modulated after the delay time t1 and the frame interval time period Tblk, and normal data driving is implemented within a time t2. However, a data driver chip already outputs a drive voltage within the delay time t1 to perform data driving on pixels for the (n+1)-th frame, causing abnormality of a voltage difference between a data voltage and the common electrode voltage within the time t1.

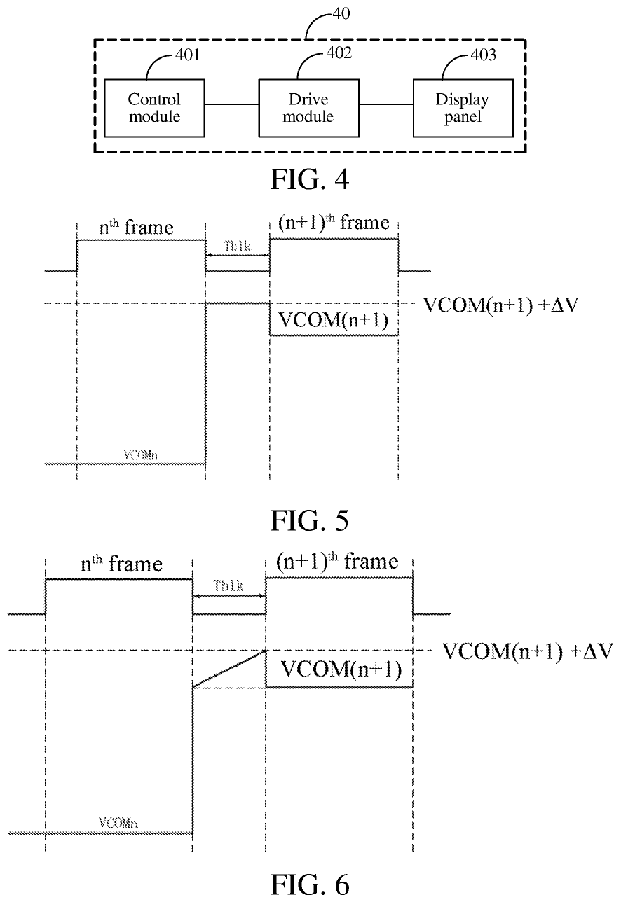

As shown in FIG. 3, an embodiment of this application provides a drive method applied to a display device, to effectively resolve a problem of modulation delay of a common electrode voltage, eliminate a color deviation phenomenon, and improve image quality. FIG. 4 shows a module structure of a display device 40 according to an embodiment of this application. The display device 40 is used as an application object of the drive method. As shown in FIG. 4, the display device 40 includes a display panel 403, a driver 402, and a controller 401. The driver 402 is electrically connected to the display panel 403, and the controller 402 is electrically connected to the driver 402. The controller 401 has functions of centralized processing and transmission of signals. A working status of the driver 402 can be changed by using the controller 401, so that the display panel 40 can display a corresponding image or corresponding video information.

The drive method provided in this embodiment includes the following steps performed by the driver of the display device:

Step S101: Modulate a common electrode voltage for an n-th frame into a target common electrode voltage within a frame interval time period.

Step S102: Modulate the target common electrode voltage into a common electrode voltage for an (n+1)-th frame when the frame interval time period ends.

The target common electrode voltage is greater than the common electrode voltage for the (n+1)-th frame which is greater than the common electrode voltage for the n-th frame, where n≥1 and n is an odd number or an even number. That is, if n is an odd number, a common electrode voltage for the 2^{nd} frame is greater than a common electrode voltage for the 1^{st} frame, a common electrode voltage for the 4^{th} frame is greater than a common electrode voltage for the 3^{rd} frame, a common electrode voltage for the 6^{th} frame is greater than a common electrode voltage for the 5^{th} frame, and the rest can be deduced by analogy. If n is an even number, a common electrode voltage for the 3^{rd} frame is greater than a common electrode voltage for the 2^{nd} frame, a common electrode voltage for the 5th frame>a common electrode voltage for the 4^{th} frame, a common electrode voltage for the 7^{th} frame is greater than a common electrode voltage for the 6^{th} frame, and the rest can be deduced by analogy.

It should be understood that the method provided in this embodiment is applicable to a case in which the common electrode voltage for the (n+1)-th frame is greater than the common electrode voltage for the n-th frame, that is, a case in which a drive polarity for the n-th frame is negative and a drive polarity for the (n+1)-th frame is positive. Polarity reversal occurs when each frame ends, so that a polarity in a next frame is different from that in a current frame.

In an application, a value of the target common electrode voltage is determined based on a value of the common electrode voltage for the (n+1)-th frame, provided that the target common electrode voltage is greater than the common electrode voltage for the (n+1)-th frame. For example, if the common electrode voltage for the (n+1)-th frame is 10 V, the target common electrode voltage may be any value greater than 10 V, for example, 11 V, 12 V, or 13 V. Further, the target common electrode voltage is regulated within the frame interval time period, so that a polarity of a pixel voltage is switched, thereby ensuring stability and safety of the pixel voltage in the display panel.

In an embodiment, step S101 includes: modulating the common electrode voltage for the n-th frame into the target common electrode voltage when the frame interval time period starts, and maintaining the target common electrode voltage unchanged within the frame interval time period.

FIG. 5 is a schematic diagram of modulation of a common electrode voltage. In FIG. 5, when the frame interval time period starts, the common electrode voltage VCOMn for the n-th frame is immediately modulated into the target common electrode voltage; the target common electrode voltage remains unchanged within the frame interval time period; and when the frame interval time period ends, the target common electrode voltage is immediately modulated into the common electrode voltage VCOM(n+1) for the (n+1)-th frame, where the target common electrode voltage=VCOM(n+1)+ΔV.

Optionally, ΔV may be set to any positive value based on an actual requirement. Further, in this embodiment, the common electrode voltage VCOMn for the n-th frame always remains at a relatively high potential within the frame interval time period, and a stable voltage can be applied to the pixels, to implement polarity switching of the pixel voltage, thereby improving a modulation speed of the common electrode voltage and accuracy of the polarity switching of the pixel voltage.

In an optional implementation, step S101 specifically includes:

outputting an excitation voltage to a common electrode wire of the display panel when the frame interval time period starts; and

increasing the common electrode voltage for the n-th frame by using the excitation voltage, so that the common electrode voltage for the n-th frame is modulated into the target common electrode voltage.

In this embodiment, the excitation voltage is used as a voltage that is additionally input into the common electrode wire in the display panel. The excitation voltage includes direct current electric energy. When the excitation voltage is applied to the common electrode wire of the display panel, the common electrode voltage for the n-th frame can be momentarily increased by using the excitation voltage, so that the common electrode voltage for the n-th frame can be quickly jumped to the target common electrode voltage, to implement a voltage polarity switching process of a common electrode voltage in each frame. Operation is easy, and the modulation speed of the common electrode voltage of the display panel is greatly improved, to avoid a color deviation phenomenon occurring in an image of the display panel.

In an optional implementation, the excitation voltage is generated by a direct current power source. For example, the excitation voltage is generated by a direct current power source of +5 V.

In an optional implementation, the target common electrode voltage gradually increases within the frame interval time period.

In this embodiment, the common electrode voltage for the n-th frame gradually increases within the frame interval time period. Therefore, power of the electric energy supplied to the common electrode wire is greater, the common electrode wire can perform power polarity switching at a higher rate, and a change rate of the pixel voltage also becomes greater, to implement polarity switching between the common electrode voltages for the n-th frame and the (n+1)-th frame, thereby better ensuring modulation safety of the target common electrode voltage. The pixel voltage can remain in a rated status after the frame interval time period ends, thereby avoiding the color deviation phenomenon occurring in the image of the display panel.

In an optional implementation, step S101 includes:

modulating the common electrode voltage for the n-th frame into the common electrode voltage for the (n+1)-th frame when the frame interval time period starts; and

modulating the common electrode voltage for the (n+1)-th frame into the target common electrode voltage at a first preset modulation speed within the frame interval time period.

As described above, the common electrode voltage for the (n+1)-th frame is greater than the common electrode voltage for the n-th frame. Therefore, when the frame interval time period starts, the common electrode voltage starts to be modulated from the common electrode voltage for the (n+1)-th frame, so that the common electrode voltage of the display panel has a higher increase speed, the change speed of the pixel voltage becomes higher, and the common electrode voltage for the n-th frame and the common electrode voltage for the (n+1)-th frame can be accurately modulated within the frame interval time period, helping to reduce a modulation time of the common electrode voltage.

Optionally, the first preset modulation speed may be set based on an actual requirement, and the modulation speed may be a constant speed, so that the common electrode voltage for the (n+1)-th frame can be linearly modulated into the target common electrode voltage. Alternatively, the modulation speed may be a jump speed changing exponentially or in a stepped manner, so that the common electrode voltage for the (n+1)-th frame can be modulated into the target common electrode voltage exponentially or in a stepped manner.

For example, the first preset modulation speed complies with a change rule of a linear function.

For example, the first preset modulation speed complies with a change rule of a quadratic function.

In this embodiment, there is a plurality of modulation methods for the common electrode voltage, to satisfy requirements on internal structures of different display panels. Therefore, a common electrode modulation method in this embodiment of this application is highly compatible and adaptive, to be applicable to common electrode voltage modulation processes in different display panels.

For example, FIG. 6 is a schematic diagram of modulation of a common electrode voltage according to an embodiment of this application. As shown in FIG. 6, when the frame interval time period starts, the common electrode voltage VCOMn for the n-th frame is immediately modulated into the common electrode voltage VCOM(n+1) for the (n+1)-th frame; the common electrode voltage VCOM(n+1) for the (n+1)-th frame is linearly modulated into the target common electrode voltage at a constant modulation speed within the frame interval time period; and when the frame interval time period ends, the target common electrode voltage is immediately modulated into the common electrode voltage VCOM(n+1) for the (n+1)-th frame, where the target common electrode voltage=VCOM(n+1)+ΔV.

In an optional implementation, step S101 includes: modulating the common electrode voltage for the n-th frame into the target common electrode voltage at a second preset modulation speed within the frame interval time period.

In this embodiment of this application, the common electrode voltage for the n-th frame is directly increased to the target common electrode voltage within the frame interval time period without other additional operation on the common electrode voltage for the n-th frame. A procedure is simplified, switching efficiency of the common electrode voltage between different frames is improved, operability of the polarity of the pixel voltage is stronger, and polarity switching efficiency is higher, thereby improving increase accuracy and stability of the common electrode voltage in the display panel.

In an optional implementation, the second preset modulation speed may be set based on an actual requirement, and the modulation speed may be a constant speed, so that the common electrode voltage for the n-th frame can be linearly modulated into the target common electrode voltage. Alternatively, the modulation speed may be a jump speed changing exponentially or in a stepped manner, so that the common electrode voltage for the n-th frame can be modulated into the target common electrode voltage exponentially or in a stepped manner.

For example, the second preset modulation speed complies with a change rule of an exponential function.

For example, the second preset modulation speed complies with a change rule of a logarithmic function.

In this embodiment of this application, the common electrode voltage for the n-th frame has a plurality of change tracks to quickly reach the target common electrode voltage, to implement a voltage polarity switching process between the n-th frame and the (n+1)-th frame. Operation is easy, the practical value is extremely high, the pixel voltage in the display panel can be stably switched, and each pixel in the display panel can emit clear image information.

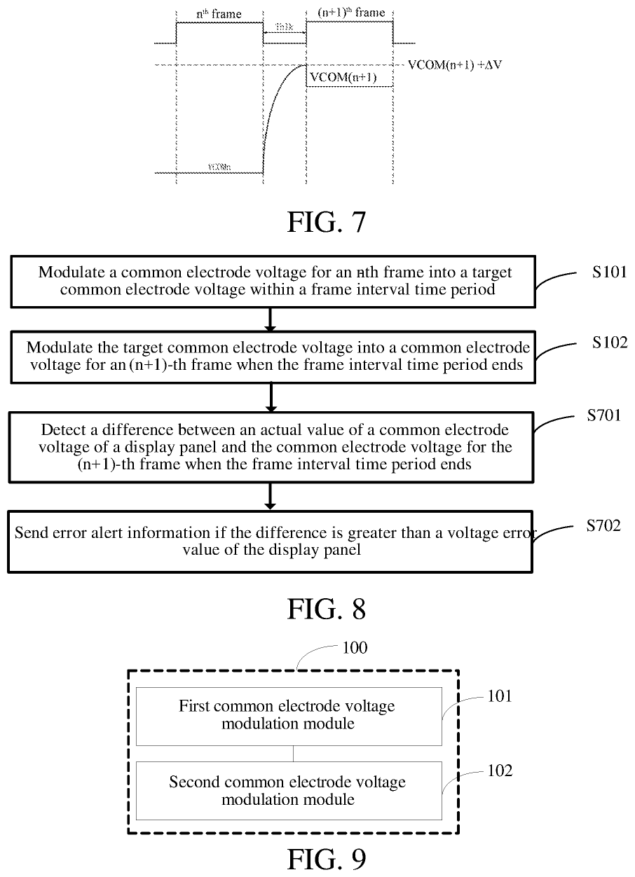

For example, FIG. 7 is a schematic diagram of modulation of a common electrode voltage according to an embodiment of this application. As shown in FIG. 7, the common electrode voltage VCOMn for the n-th frame is modulated into the target common electrode voltage at an inconstant modulation speed in an exponential change manner within the frame interval time period. When the frame interval time period ends, the target common electrode voltage is immediately modulated into the common electrode voltage VCOM(n+1) for the (n+1)-th frame, where the target common electrode voltage=VCOM(n+1)+ΔV.

In an optional implementation, a lower-limit voltage that is output by the driver is smaller than or equals to the target common electrode voltage≤an upper-limit voltage that is output by the driver, that is, a maximum value of the target common electrode voltage may be a maximum voltage value that can be output by the driver of the display device, to ensure that a stable voltage can be applied to the pixels of the display panel, so that the display panel remains in a normal and stable working status, thereby improving pixel safety of the display panel.

In an optional implementation, FIG. 8 shows other operation steps of the drive method applied to a display device according to an embodiment of this application. Compared with the drive method in FIG. 3, the drive method in FIG. 8 further includes the following steps:

Step S701: Detect a difference between an actual value of a common electrode voltage of the display panel and the common electrode voltage for the (n+1)-th frame when the frame interval time period ends.

Step S702: Send error alert information if the difference is greater than a voltage error value of the display panel.

In this embodiment of this application, the difference between the actual value of the common electrode voltage and the common electrode voltage for the (n+1)-th frame is detected when the frame interval time period ends to determine polarity switching of the pixel voltage in the display panel, to obtain whether the polarity of the common electrode voltage in the display panel is modulated and recognize stability of the pixel voltage. In addition, if an amplitude of the difference between the actual value of the common electrode voltage and the common electrode voltage for the (n+1)-th frame is greater than the voltage error of the display panel, it indicates that the pixel voltage in the display panel fails to be switched. For the (n+1)-th frame, the common electrode voltage of the display panel remains in an insufficient running status, and a color deviation phenomenon easily occurs in the display panel. In this case, the error alert information is sent to inform the technical personnel that: the polarity switching process of the pixel voltage of the display panel remains in a fault state, and the technical personnel may detect a pixel circuit of the display panel according to the error alert information, to clear a circuit fault, thereby avoiding a color deviation phenomenon caused by lack of precise switching of the common electrode voltage in the display panel, and ensuring image quality in the display panel.

In an optional implementation, the voltage error value is determined based on a parameter of an internal circuit structure of the display panel. In an actual application process, when the display panel has different internal circuit structures, a specific value of the voltage error value varies.

In an optional implementation, the drive method includes:

modulating the common electrode voltage for the n-th frame into the target common electrode voltage when the frame interval time period starts; and

modulating the target common electrode voltage into the common electrode voltage for the (n+1)-th frame within the frame interval time period, where

the target common electrode voltage is greater than the common electrode voltage for the (n+1)-th frame which is greater than the common electrode voltage for the n-th frame, where n≥1 and n is an odd number or an even number.

In an optional implementation, the modulating the target common electrode voltage into the common electrode voltage for the (n+1)-th frame within the frame interval time period includes:

modulating the target common electrode voltage into the common electrode voltage for the (n+1)-th frame at a third modulation speed within the frame interval time period.

In an optional implementation, the drive method includes:

modulating the common electrode voltage for the n-th frame into the target common electrode voltage at a fourth modulation speed within the first half of the frame interval time period; and

modulating the target common electrode voltage into the common electrode voltage for the (n+1)-th frame at a fifth modulation speed within the second half of the frame interval time period, where

the target common electrode voltage is greater than the common electrode voltage for the (n+1)-th frame which is greater than the common electrode voltage for the n-th frame, where n≥1 and n is an odd number or an even number.

In an application, the third preset modulation speed, the fourth modulation speed, and the fifth modulation speed may be set based on an actual requirement. The modulation speed may be a constant speed, or may be a jump speed changing exponentially or in a step manner.

In this embodiment, the common electrode voltage for the n-th frame is modulated into the target common electrode voltage within the frame interval time period, so that the target common electrode voltage is greater than the common electrode voltage for the (n+1)-th frame which is greater than the common electrode voltage for the n-th frame, and the target common electrode voltage is modulated into the common electrode voltage for the (n+1)-th frame when the frame interval time period ends, so that the modulation time of the common electrode voltage can be shortened, and the modulation speed of the common electrode voltage can be improved, thereby reducing display color deviation in the display device and improving image quality.

FIG. 9 shows a module structure of a drive system 100 according to an embodiment of this application. The drive system 100 is applied to a display device, where the display device includes a display panel, a driver, and a controller, the driver is electrically connected to the display panel, the controller is electrically connected to the driver, and the drive system 100 includes the following program modules executed by the driver of the display device:

a first common electrode voltage modulator 101, configured to modulate a common electrode voltage for an n-th frame into a target common electrode voltage within a frame interval time period; and

a second common electrode voltage modulator 102, configured to modulate the target common electrode voltage into a common electrode voltage for an (n+1)-th frame when the frame interval time period ends, where

the target common electrode voltage is greater than the common electrode voltage for the (n+1)-th frame which is greater than the common electrode voltage for the n-th frame, where n≥1 and n is an odd number or an even number.

In an optional implementation, the first common electrode voltage modulator and the second common electrode voltage modulator may be program modules in the controller of the display device, or may be drive circuits in a data driver component in the display device.

In an embodiment, the controller may be a timing controller (TCON), and the data driver component may be a source driver IC. The controller or the data driver component may alternatively be implemented by using a universal integrated circuit such as a central processing unit (CPU) or by using an application-specific integrated circuit (ASIC) or a field programmable logic gate device.

In an embodiment, the first common electrode voltage modulator is configured to modulate the common electrode voltage for the n-th frame into the target common electrode voltage when the frame interval time period starts, and maintain the target common electrode voltage unchanged within the frame interval time period.

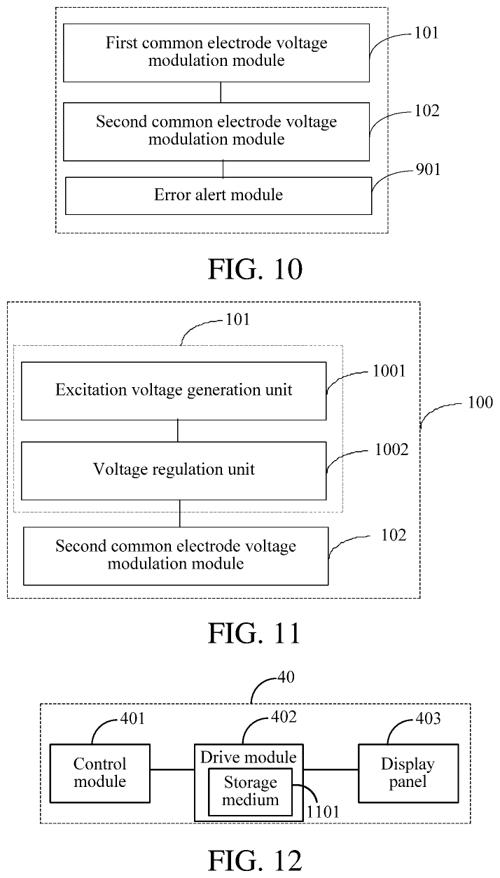

In an optional implementation, FIG. 10 shows a module structure of another drive system 100 according to an embodiment. Compared with the module structure of the drive system in FIG. 9, the drive system in FIG. 10 further includes an error alertor 901.

The error alertor 901 is configured to detect a difference between an actual value of a common electrode voltage of the display panel and the common electrode voltage for the (n+1)-th frame when the frame interval time period ends, and send error alert information if the difference is greater than a voltage error value of the display panel.

In an optional implementation, the error alertor 901 may be implemented by using a fire alarm horn strobe or an alert circuit in the exemplary technology. Further, in this embodiment of this application, the error alertor 901 can detect polarity switching of a pixel voltage, to improve switching efficiency of the common electrode voltage of the display panel. The pixel voltage on which polarity switching is performed in the display panel can reach a rated voltage status, to avoid a severe color deviation phenomenon in an image in the display panel, and improve quality of the image in the display panel.

In an embodiment, FIG. 11 shows a specific module structure of the first common electrode voltage modulator 101 according to an embodiment. As shown in FIG. 11, the first common electrode voltage modulator 101 includes:

an excitation voltage generator 1001, configured to output an excitation voltage to a common electrode wire of the display panel when the frame interval starts; and

a voltage regulator 1002, configured to increase the common electrode voltage for the n-th frame by using the excitation voltage within the frame interval time period, so that the common electrode voltage for the n-th frame is modulated into the target common electrode voltage.

In an optional implementation, the excitation voltage generator 1001 is a direct current power source, and the voltage regulator 1002 is implemented by using a voltage-modulating circuit in the exemplary technology. Therefore, in the drive system 100 in this embodiment of this application, the voltage regulator 1002 can change the common electrode voltage of the display panel by using the excitation voltage, so that a polarity of the pixel voltage of the display panel is quickly switched between different frames, thereby improving a modulation speed and accuracy of the common electrode voltage of the display panel.

In an optional implementation, the first common electrode voltage modulator 101 is configured to:

modulate the common electrode voltage for the n-th frame into the common electrode voltage for the (n+1)-th frame when the frame interval time period starts; and

modulate the common electrode voltage for the (n+1)-th frame into the target common electrode voltage at a first preset modulation speed within the frame interval time period.

In an optional implementation, the first preset modulation speed complies with a change rule of a linear function. Alternatively, the first preset modulation speed complies with a change rule of a quadratic function.

In an embodiment, the first common electrode voltage modulator 101 is configured to modulate the common electrode voltage for the n-th frame into the target common electrode voltage at a second preset modulation speed within the frame interval time period.

In an optional implementation, the second preset modulation speed complies with a change rule of an exponential function. Alternatively, the second preset modulation speed complies with a change rule of a logarithmic function.

In an optional implementation, a lower-limit voltage that is output by the driver is smaller than or equals to the target common electrode voltage which is smaller than or equals to an upper-limit voltage that is output by the driver.

In the drive system 100 in this embodiment of this application, the first common electrode voltage modulator 101 can quickly modulate the common electrode voltage for the n-th frame into the target common electrode voltage, and there is a plurality of modulation speeds, so that the polarity of the pixel voltage in this embodiment of this application can be quickly regulated within the frame interval time period. A polarity of the common electrode voltage of the display panel can be quickly switched, and the common electrode voltage can always remain in a stable working status in each frame of image of the display panel, to avoid a problem in the exemplary technology that displaying of the display panel has relatively large deviation because the voltage polarity of the display panel cannot be switched within the frame interval time period.

In an embodiment, the drive system includes:

the first common electrode voltage modulator, configured to modulate the common electrode voltage for the n-th frame into the target common electrode voltage when the frame interval time period starts; and

the second common electrode voltage modulator, configured to modulate the target common electrode voltage into the common electrode voltage for the (n+1)-th frame within the frame interval time period starts, where

the target common electrode voltage is greater than the common electrode voltage for the (n+1)-th frame which is greater than the common electrode voltage for the n-th frame, where n≥1 and n is an odd number or an even number.

In an embodiment, the second common electrode voltage modulator is configured to modulate the target common electrode voltage into the common electrode voltage for the (n+1)-th frame at a third modulation speed within the frame interval time period.

In an embodiment, the drive system includes:

the first common electrode voltage modulator, configured to modulate the common electrode voltage for the n-th frame into the target common electrode voltage at a fourth modulation speed within the first half of the frame interval time period; and

the second common electrode voltage modulator, configured to modulate the target common electrode voltage into the common electrode voltage for the (n+1)-th frame a at a fifth modulation speed within the second half of the frame interval time period, where

the target common electrode voltage is greater than the common electrode voltage for the (n+1)-th frame which is greater than the common electrode voltage for the n-th frame, where n≥1 and n is an odd number or an even number.

It should be noted that the drive system 100 shown in FIG. 9 to FIG. 11 corresponds to the drive method for a display device in FIG. 3 to FIG. 8. Therefore, for specific implementations of the drive system 100 in FIG. 9 to FIG. 11, refer to the embodiments in FIG. 3 to FIG. 8, and details are not described herein again.

In this embodiment, the common electrode voltage for the n-th frame is modulated into the target common electrode voltage within the frame interval time period, so that the target common electrode voltage is greater than the common electrode voltage for the (n+1)-th frame which is greater than the common electrode voltage for the n-th frame, and the target common electrode voltage is modulated into the common electrode voltage for the (n+1)-th frame when the frame interval time period ends, so that a modulation time of the common electrode voltage can be shortened, and a modulation speed of the common electrode voltage can be improved, thereby reducing display color deviation in the display device and improving image quality.

FIG. 12 shows a module structure of a display device 110 according to an embodiment of this application. The display device 110 includes: a display panel 403, a driver 402, and a controller 401, where the driver 402 is electrically connected to the display panel 403, the controller 401 is electrically connected to the driver 402, the driver 402 includes a storage medium 1101, the storage medium 1101 stores a computer program, when the program is executed by a processor, the following drive method for a display device is implemented, and the drive method includes:

modulating a common electrode voltage for an n-th frame into a target common electrode voltage within a frame interval time period; and

modulating the target common electrode voltage into a common electrode voltage for an (n+1)-th frame when the frame interval time period ends, where

the target common electrode voltage is greater than the common electrode voltage for the (n+1)-th frame which is greater than the common electrode voltage for the n-th frame, where n≥1 and n is an odd number or an even number.

The display device 110 in FIG. 12 corresponds to the drive method for a display device in FIG. 3 to FIG. 8. Therefore, for the internal module structure of the display device 110 in FIG. 12 and a working principle thereof, refer to the embodiments in FIG. 3 to FIG. 8, and details are not described herein again.

In this embodiment of this application, the driver 402 can change the common electrode voltage in the display panel, so that the common electrode voltage in the display panel can be quickly switched within the frame interval time period, a common electrode voltage in each frame in an image of the display panel remains in a stable working status, a polarity of a pixel voltage can be stably modulated between different frames, and pixels in the display panel can remain in a rated working status, thereby reducing electric energy loss generated in a polarity switching process of the pixel voltage in the display panel, eliminating a color deviation phenomenon in the image in the display panel, improving visual experience of a user, and effectively resolving a problem in the exemplary technology that the color deviation phenomenon occurs in the voltage polarity switching process of the pixels in the display device because the polarity of the common electrode voltage of the display device cannot be stably switched within the frame interval time period.

In an embodiment, the display device may be any type of display device, for example, a liquid crystal display (LCD) display device, an organic light-emitting diode (OLED) display device, a quantum dot light emitting diode (QLED) display device, or a curved display device. The display panel is a display panel corresponding to the type of the display device.

In an application, the display panel includes a light filter substrate, a pixel array, and an array substrate that are sequentially laminated.

In an application, the light filter substrate may be any substrate that can achieve a light filter function, for example, a color filter substrate including a color filter.

In an application, the pixel array may include a plurality of sub-pixels regularly arranged in any shape, for example, may include a plurality of rows of sub-pixels regularly arranged in a rectangular shape. Each row of sub-pixels in the pixel array includes a plurality of groups of sub-pixels, and each group of sub-pixels includes a first color sub-pixel, a second color sub-pixel, and a third color sub-pixel that are sequentially arranged. Sub-pixels in a same column have a same color. The first color sub-pixel, the second color sub-pixel, and the third color sub-pixel include at least one red cub-pixel, at least one green sub-pixel, and at least one blue sub-pixel.

In an embodiment, the controller may be a TCON, and the driver may be a source driver IC. The controller or a data driver component may alternatively be implemented by using a universal integrated circuit.

The modules or sub-modules in all the embodiments of this application may be implemented by using a universal integrated circuit, for example, a CPU, or by using an ASIC.

The steps in the methods of the embodiments of this application may be reordered, combined, or deleted according to actual needs.

The modules in the apparatus of the embodiments of this application may be combined, divided, or deleted according to actual needs.

A person of ordinary skill in the art may understand that all or some of the processes of the methods in the embodiments may be implemented by a computer program instructing relevant hardware. The program may be stored in a computer readable storage medium. When the program runs, the processes of the methods in the embodiments are performed. The foregoing storage medium may include: a magnetic disk, an optical disc, a read-only memory (ROM), or a random access memory (RAM).

The above descriptions are merely optional embodiments of this application, and are not intended to limit this application. It should be understood by persons skilled in the art that various modifications and variations can be made to this application. Any modification, equivalent replacement, or improvement made without departing from the spirit and principle of this application shall fall within the scope as defined by the appended claims.

1-20. (canceled)

21. A drive method for a display device, wherein the display device comprises a display panel, a driver, and a controller, the driver is electrically connected to the display panel, the controller is electrically connected to the driver, the controller is configured to control the driver to perform the following drive method, and the drive method comprises:
modulating a common electrode voltage for an n-th frame into a target common electrode voltage within a frame interval time period; and
modulating the target common electrode voltage into a common electrode voltage for an (n+1)-th frame before the frame interval time period ends,
wherein the target common electrode voltage is greater than the common electrode voltage for the (n+1)-th frame which is greater than the common electrode voltage for the n-th frame, wherein n≥1 and n is selected from an odd number and an even number.

22. The drive method for a display device according to claim 21, wherein the step of modulating a common electrode voltage for an n-th frame into a target common electrode voltage within a frame interval time period comprises:
modulating the common electrode voltage for the n-th frame into the target common electrode voltage when the frame interval time period starts, and maintaining the target common electrode voltage unchanged within the frame interval time period.

23. The drive method for a display device according to claim 21, wherein the drive method further comprises:
detecting a difference between an actual value of a common electrode voltage of the display panel and the common electrode voltage for the (n+1)-th frame when the frame interval time period ends; and
sending error alert information in the case that the difference is greater than a voltage error value of the display panel.

24. The drive method for a display device according to claim 21, wherein the step of modulating a common electrode voltage for an n-th frame into a target common electrode voltage within a frame interval time period comprises:
outputting an excitation voltage to a common electrode wire of the display panel when the frame interval time period starts; and
increasing the common electrode voltage for the n-th frame by using the excitation voltage, so that the common electrode voltage for the n-th frame is modulated into the target common electrode voltage.

25. The drive method for a display device according to claim 21, wherein the target common electrode voltage increases within the frame interval time period.

26. The drive method for a display device according to claim 25, wherein the step of modulating a common electrode voltage for an n-th frame into a target common electrode voltage within a frame interval time period comprises:
modulating the common electrode voltage for the n-th frame into the common electrode voltage for the (n+1)-th frame when the frame interval time period starts; and
modulating the common electrode voltage for the (n+1)-th frame into the target common electrode voltage at a first preset modulation speed within the frame interval time period.

27. The drive method for a display device according to claim 26, wherein the first preset modulation speed complies with a change rule of a linear function, or the first preset modulation speed complies with a change rule of a quadratic function.

28. The drive method for a display device according to claim 25, wherein the step of modulating a common electrode voltage for an n-th frame into a target common electrode voltage within a frame interval time period comprises:
modulating the common electrode voltage for the n-th frame into the target common electrode voltage at a second preset modulation speed within the frame interval time period.

29. The drive method for a display device according to claim 28, wherein the second preset modulation speed complies with a change rule of an exponential function, or the second preset modulation speed complies with a change rule of a logarithmic function.

30. The drive method for a display device according to claim 21, wherein a lower-limit voltage that is output by the driver is smaller than or equals to the target common electrode voltage which is smaller than or equals to an upper-limit voltage that is output by the driver.

31. A drive system for a display device, wherein the display device comprises a display panel, a driver, and a controller, the driver is electrically connected to the display panel, the controller is electrically connected to the driver, the controller is configured to control the driver to execute program modules in the following drive system, and the drive system comprises:
a first common electrode voltage modulator configured to modulate a common electrode voltage for an n-th frame into a target common electrode voltage within a frame interval time period; and
a second common electrode voltage modulator configured to modulate the target common electrode voltage into a common electrode voltage for an (n+1)-th frame before the frame interval time period ends,
wherein the target common electrode voltage is greater than the common electrode voltage for the (n+1)-th frame which is greater than the common electrode voltage for the n-th frame, wherein n≥1 and n is selected from an odd number and an even number.

32. The drive system for a display device according to claim 31, wherein the first common electrode voltage modulator is configured to modulate the common electrode voltage for the n-th frame into the target common electrode voltage when the frame interval time period starts, and maintain the target common electrode voltage unchanged within the frame interval time period.

33. The drive system for a display device according to claim 31, wherein the drive system further comprises:
an error alertor, configured to detect a difference between an actual value of a common electrode voltage of the display panel and the common electrode voltage for the (n+1)-th frame when the frame interval time period ends, and send error alert information in the case that the difference is greater than a voltage error value of the display panel.

34. The drive system for a display device according to claim 31, wherein the first common electrode voltage modulator comprises:
an excitation voltage generator configured to output an excitation voltage to a common electrode wire of the display panel when the frame interval time period starts; and
a voltage regulator configured to increase the common electrode voltage for the n-th frame by using the excitation voltage within the frame interval time period, so that the common electrode voltage for the n-th frame is modulated into the target common electrode voltage.

35. The drive system for a display device according to claim 31, wherein the first common electrode voltage modulator is configured to:
modulate the common electrode voltage for the n-th frame into the common electrode voltage for the (n+1)-th frame when the frame interval time period starts; and
modulate the common electrode voltage for the (n+1)-th frame into the target common electrode voltage at a first preset modulation speed within the frame interval time period.

36. The drive system for a display device according to claim 35, wherein the first preset modulation speed complies with a change rule of a linear function, or the first preset modulation speed complies with a change rule of a quadratic function.

37. The drive system for a display device according to claim 31, wherein the first common electrode voltage modulator is configured to modulate the common electrode voltage for the n-th frame into the target common electrode voltage at a second preset modulation speed within the frame interval time period.

38. The drive system for a display device according to claim 37, wherein the second preset modulation speed complies with a change rule of an exponential function, or the second preset modulation speed complies with a change rule of a logarithmic function.

39. The drive system for a display device according to claim 31, wherein a lower-limit voltage that is output by the driver is smaller than or equals to the target common electrode voltage which is smaller than or equals to an upper-limit voltage that is output by the driver.

40. A display device, comprising a display panel, a driver, and a controller, wherein the driver is electrically connected to the display panel, the controller is electrically connected to the driver, the driver comprises a storage medium with a computer program stored therein, when the program is executed by a processor, the following drive method for the display device is implemented, and the drive method comprises:
modulating a common electrode voltage for an n-th frame into a target common electrode voltage within a frame interval time period; and
modulating the target common electrode voltage into a common electrode voltage for an (n+1)-th frame before the frame interval time period ends, wherein
the target common electrode voltage is greater than the common electrode voltage for the (n+1)-th frame which is greater than the common electrode voltage for the n-th frame,
wherein n≥1 and n is selected from an odd number and an even number.
